(19) United States
(12) Patent Application Publication
(10) Pub. No.: US 2025/0393231 A1
(43) Pub. Date: Dec. 25, 2025

(54) SEMICONDUCTOR DEVICE GATE SKIRT MODIFICATION

(71) Applicant: International Business Machines Corporation, Armonk, NY (US)

(72) Inventors: Mohamed Abdelmaksoud Mohamed Rabie, Clifton Park, NY (US); Dureseti Chidambarrao, Weston, CT (US); Jingyun Zhang, Albany, NY (US)

(21) Appl. No.: 18/751,553

(22) Filed: Jun. 24, 2024

(51) Int. Cl. H01L 29/66; H01L 21/306; H01L 21/321; H01L 29/06; H01L 29/417; H01L 29/775; H01L 29/786

(52) U.S. Cl. CPC H10D 30/014; H01L 21/306; H01L 21/32105; H01L 21/3211; H10D 64/017; H10D 64/258; H10D 30/43; H10D 30/6757; H10D 62/121

(57) ABSTRACT

A semiconductor device includes a semiconductor substrate with an insulator layer surrounding a semiconductor fin, and a semiconductor material stack structure on the semiconductor fin. Agate spacer covers the sacrificial gate structure and the semiconductor material stack structure. The semiconductor device further includes gate spacer extensions on the insulator layer and against sidewalls of the semiconductor material stack structure.

### BACKGROUND

The present invention generally relates to fabrication methods and resulting structures for integrated circuits, and more specifically, to fabrication methods and resulting structures that provide yield and variation improvement for nanosheet semiconductor devices.

The use of non-planar semiconductor devices such as, for example, a nanosheet containing device is the next step in the evolution of complementary metal oxide semiconductor (CMOS) devices. By “nanosheet containing device” it is meant that the device contains one or more layers of semiconductor channel material portions (i.e., a stack of nanosheets) having a vertical thickness that is substantially less than its width. Nanosheet containing device formation relies on the selective removal of a sacrificial semiconductor material (e.g., a silicon germanium alloy) with respect to a semiconductor channel material (e.g., silicon) to form suspended nanosheets for gate-all-around devices.

### SUMMARY

According to a non-limiting embodiment, a semiconductor device includes a semiconductor substrate with an insulator layer surrounding a semiconductor fin, and a semiconductor material stack structure on the semiconductor fin. Gate spacers cover the sacrificial gate structure and the semiconductor material stack structure. The semiconductor device further includes gate spacer extensions on the insulator layer and against sidewalls of the semiconductor material stack structure.

According to another non-limiting embodiment, a method of fabricating a semiconductor device is provided. The method comprises etching a dummy gate material to form a sacrificial gate structure and expose a semiconductor material stack structure that will be replaced with source/drain regions on opposing sides of the sacrificial gate structure. A remaining amount of the dummy gate material defines a gate skirt located at an interface shared by the semiconductor material stack structure and the sacrificial gate structure. The method further includes forming gate spacers that cover the sacrificial gate structure, the semiconductor material stack structure, and the gate skirt, and etching a portion of the gate spacers to expose the semiconductor material stack structure and at least a portion of the gate skirt. The method further comprises performing a nitridation process that converts the portion of the gate skirt into a nitride plug.

According to yet another non-limiting embodiment, a method of fabricating a semiconductor device is provided. The method comprises etching a dummy gate material to form a sacrificial gate structure and expose a semiconductor material stack structure. A remaining amount of the dummy gate material defines a gate skirt located at an interface shared by the semiconductor material stack structure and the sacrificial gate structure. The method further comprises performing a thermal oxidation process to form an oxide film that covers the sacrificial gate structure and consumes at least a portion of the gate skirt and cover it, and etching the oxide film. The method further comprises forming gate spacers that cover the sacrificial gate structure and the semiconductor material stack structure. The method further comprises replacing layers of sacrificial semiconductor material included in the semiconductor material stack structure with inner dielectric spacers.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A and 1B depict a semiconductor device following various fabrication operations according to one or more embodiments of the invention;

FIGS. 2A and 2B depict the semiconductor device following formation of sacrificial gate structures according to one or more embodiments of the invention;

FIGS. 3A and 3B depict the semiconductor device after forming an extended gate dielectric from a semiconductor material stack structure according to one or more embodiments of the invention;

FIGS. 4A and 4B depict the semiconductor device following formation of gate spacers according to one or more embodiments of the invention;

FIG. 5 depicts the semiconductor after etching a portion of the gate spacer from the semiconductor material stack structure according to one or more embodiments of the invention;

FIG. 6 depicts the semiconductor after performing a nitridation process according to one or more embodiments of the invention;

FIG. 7 depicts the semiconductor after removing a nitride liner from the semiconductor material stack structure according to one or more embodiments of the invention;

FIG. 8 depicts the semiconductor after recessing the sacrificial semiconductor material included in the semiconductor material stack structure according to one or more embodiments of the invention;

FIG. 9 depicts the semiconductor device after forming an inner dielectric spacer in the semiconductor material stack structure according to one or more embodiments of the invention;

FIG. 10 depicts a semiconductor device following various fabrication operations according to one or more embodiments of the invention;

FIGS. 11A and 11B depict the semiconductor device following a thermal oxidation process according to one or more embodiments of the invention;

FIG. 12 depicts the semiconductor device after removing gate dielectric from source/drain regions of the semiconductor material stack structures according to one or more embodiments of the invention;

FIG. 13 depicts the semiconductor device after forming a gate spacer on a sidewall of the sacrificial gate structure according to one or more embodiments of the invention;

FIG. 14 depicts the semiconductor device after recessing the gate spacer and a portion of the semiconductor material stack structure located in the source/drain region according to one or more embodiments of the invention;

FIG. 15 depicts the semiconductor device after recessing each layer of the sacrificial semiconductor material according to one or more embodiments of the invention; and

FIG. 16 depicts the semiconductor device after forming an inner dielectric spacer in the semiconductor material stack structure according to one or more embodiments of the invention.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

During the fabrication of a nanosheet Field-Effect Transistors (FETs), the dummy gate formation via reactive ion etching (RIE) of the dummy gate material (e.g., amorphous silicon (aSi)) can encounter issues due to etch rate variations influenced by topographical changes at the interface between the active region (RX) and shallow trench isolation (STI) edges. These variations can lead to the formation of an unintended “gate skirt,” which is a residual amount of the dummy gate material that remains at these edges following the dummy gate RIE. This gate skirt is problematic as it introduces irregularities that disrupt the subsequent processing steps, particularly affecting the integrity of the source and drain regions.

The gate skirt causes two primary issues. First, it can lead to the formation of buried voids within the epitaxial layer, which occur due to the uneven surface created by the excess material. The void can also occur when an exposed portion of the skirt is recessed when selectively recessing the sacrificial semiconductor material of the nanosheet stack. These voids act as defects that degrade the electrical performance of the transistor, potentially causing poor conductivity or complete disconnections. Second, the presence of the gate skirt introduces significant variability in the dimensions and properties of the gate and channel regions, resulting in inconsistencies in device performance. This variability manifests as threshold voltage shifts, changes in drive current, and unpredictable leakage currents, which collectively impact the uniformity and reliability of the transistors across a chip.

To address these issues, the present disclosure describes fabrication methods and resulting structures that provide yield and variation improvement for nanosheet semiconductor devices. According to a non-limiting embodiment, a fabrication process described herein forms a spacer that covers the gate skirt. Accordingly, the gate skirt is not exposed when removing the sacrificial semiconductor material from the nanosheet stack, thereby avoiding the formation of a void at the active region (RX) and shallow trench isolation (STI) edges.

According to another non-limiting embodiment, a fabrication process described herein performs a nitridation process prior to removing the sacrificial semiconductor material from the nanosheet stack. The nitridation process converts the dummy gate material of any exposed portions of the gate skirt into a nitride material. The sacrificial semiconductor material from the nanosheet stack can then be selectively recessed with respect to the semiconductor channel material and the nitride material. Accordingly, the silicon nitride material effectively serves as a “nitride plug” that plugs the void that would have occurred had the gate skirt been exposed when recessing the sacrificial semiconductor material.

In either embodiment discussed above, the gate skirt is unexposed when performing the sacrificial semiconductor material recess. In this manner, a portion of the layers of sacrificial semiconductor material included in the semiconductor material stack can be replaced with inner dielectric spacers and/or gate metals without forming the undesirable void that occurs in conventional fabrication processes.

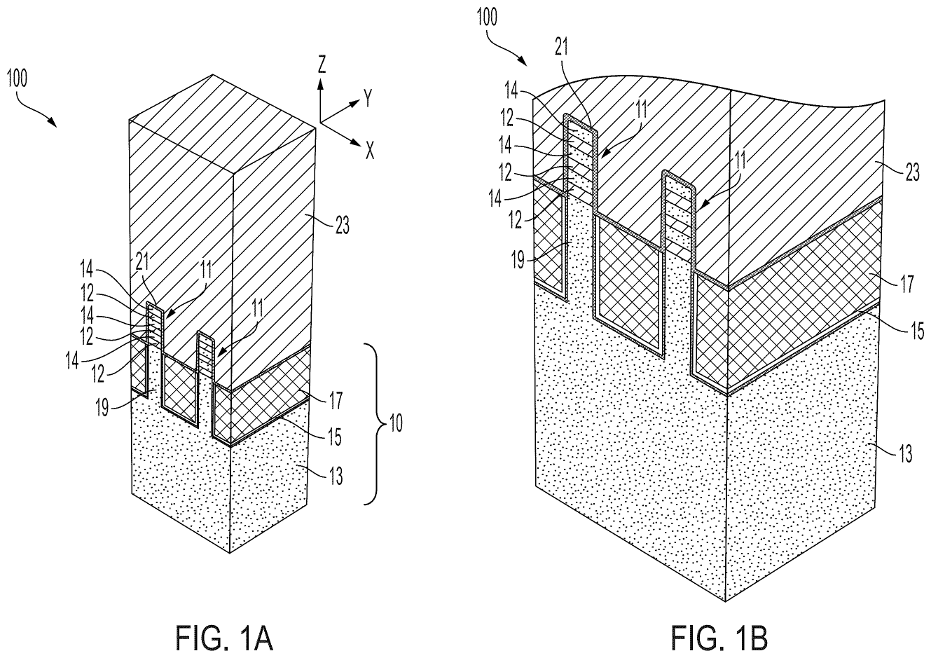

FIGS. 1A-9 depict various fabrication operations for forming a semiconductor device 100 that provides yield and variation improvement for a nanosheet semiconductor device according to non-limiting embodiments of the present disclosure. As described herein, standard semiconductor fabrication techniques can be utilized to fabricate the semiconductor device as understood by one of ordinary skill in the art. Any suitable deposition techniques and etching techniques can be utilized herein.

Turning now to a more detailed description of aspects of the present disclosure, FIGS. 1A and 1B depict a semiconductor device 100 following several fabrication operations. The semiconductor device 100 extends along a first axis (e.g., X-axis) to define a length, a second axis (e.g., Y-axis) orthogonal to the first axis to define a width, and a third axis (e.g., Z-axis) orthogonal to the first and second axes to define a height. It should be appreciated that that FIGS. 1A and 1B are three-dimensional cross sectional views of the semiconductor device 100, which may continuously extend to another semiconductor device (not shown).

The exemplary semiconductor device 100 of FIGS. 1A and 1B include one or more semiconductor material stack structures 11 of alternating layers of a sacrificial semiconductor material 12 and a semiconductor channel material 14 on a surface of a semiconductor substrate 10. The layers of sacrificial semiconductor material 12 define sacrificial nanosheets and the layers of semiconductor channel material 14 define channel nanosheets. Although, FIG. 1B illustrates two semiconductor material stack structures 11 that are orientated parallel to each other, the present disclosure is not limited to the formation of two semiconductor material stack structures 11. Instead, the present disclosure can be employed when a single semiconductor material stack structure 11 is formed, or more than two semiconductor material stack structures 11 are formed.

In at least one non-limiting embodiment of the disclosure, the semiconductor substrate 10 can include a base 13, a substrate liner 15, and an insulator layer 17. The base 13 can include one or semiconductor fins 19. Examples of semiconductor materials that can be used to form the base 13 and semiconductor fins 19 include, but are not limited to, silicon (Si), a silicon germanium (SiGe) alloy, a silicon germanium carbide (SiGeC) alloy, germanium (Ge), III/V compound semiconductors or II/VI compound semiconductors. The substrate liner 15 can be formed using various nitride materials such as, for example, silicon nitride (SiN). The insulator layer 17 can be formed around the semiconductor fins 19 to define a shallow trench isolation (STI) region. The insulator layer 17 can be formed from an oxide material, a dielectric material crystalline or a non-crystalline dielectric material. In one example, the insulator layer 17 can include of silicon dioxide (SiO₂).

In some embodiments, the semiconductor substrate 10 is a bulk substrate. The term “bulk substrate” denotes a semiconductor substrate 10 that is composed entirely of one or more semiconductor materials. In one example, the bulk substrate is composed entirely of Si. In another embodiment, the semiconductor substrate 10 is a silicon-on-insulator (SOI) substrate.

As mentioned above, semiconductor material stack structure 11 includes alternating layers of a sacrificial semiconductor material 12 and a semiconductor channel material 14 stacked one atop the other and such that each layer of a semiconductor channel material 14 is located between a bottom layer of sacrificial semiconductor material 12 and a top layer of sacrificial semiconductor material 12. In FIGS. 1A-1B and by way of one example, the semiconductor material stack structure 11 includes three layers of sacrificial semiconductor material 12 and three layers of semiconductor channel material 14. The semiconductor material stack structure 11 that can be employed in the present disclosure is not limited to the specific embodiment illustrated in FIGS. 1A-1B. Instead, the semiconductor material stack structure 11 can include any number of layers of sacrificial semiconductor material 12 and corresponding layers of semiconductor channel material 14 provided that each layer of a semiconductor channel material 14 is located between a bottom layer of sacrificial semiconductor material 12 and a top layer of sacrificial semiconductor material 12.

Each layer of sacrificial semiconductor material 12 is composed of a first type of semiconductor material which differs in composition from at least the semiconductor fins 19 of the semiconductor substrate 10. In one embodiment, the semiconductor fins 19 are formed from Si, while each layer of sacrificial semiconductor material 12 is composed of a silicon germanium (SiGe).

Each layer of semiconductor channel material 14 is composed of a second type semiconductor material that is different from the first type of semiconductor material provided for the sacrificial semiconductor material 12. For example, the second type of semiconductor material provided for the semiconductor channel material 14 can have a different etch rate than the first semiconductor material of sacrificial semiconductor material 12. The second semiconductor material that provides each layer of semiconductor channel material 14 may be the same as, or different from, the semiconductor material that provides at least the upper portion of the semiconductor substrate 10. In one example, the semiconductor fins 19 and each layer of semiconductor channel material 14 are composed of Si or a III-V compound semiconductor, while each layer of sacrificial semiconductor material 12 is composed of SiGe or a III-V compound semiconductor that is different from the one used as the semiconductor channel material 14.

The semiconductor material stack structure 11 can be formed by sequential epitaxial growth of alternating layers of the sacrificial semiconductor material 12 and the semiconductor channel material 14. Following epitaxial growth of the topmost layer (e.g., the topmost semiconductor channel material 14) of the semiconductor material stack structure 11 a patterning process may be used to provide the semiconductor material stack structure 11 shown in FIGS. 1A-1B. Patterning can be performed by lithography and etching or any other patterning method known to those skilled in the art including, for example, a sidewall-image transfer (SIT) process.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Examples of various epitaxial growth process apparatuses that can be employed in the present disclosure include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking. The epitaxial growth of the first and second semiconductor materials that provide the layers of sacrificial semiconductor material 12 and the layers of semiconductor channel material 14, respectively, can be performed utilizing any well-known precursor gas or gas mixture. Carrier gases like hydrogen, nitrogen, helium and argon can be used.

The term “semiconductor material stack structure” denotes a continuous fin-like structure including a pair of vertical sidewalls that are parallel to each other. As used herein, a surface is “vertical” if there exists a vertical plane from which the surface does not deviate by more than three times the root mean square roughness of the surface. Each layer of sacrificial semiconductor material 12 may have a thickness from 3 nm to 30 nm, while each layer of semiconductor channel material 14 may have a thickness from 3 nm to 20 nm. Each layer of sacrificial semiconductor material 12 may have a thickness that is the same as, or different from, a thickness of each layer of semiconductor channel material 14.

Following formation of the semiconductor material stack structures 11, a gate dielectric 21 is formed on the semiconductor material stack structures 11 and a dummy gate layer 23 is formed on the semiconductor substrate 10. The gate dielectric 21 can be formed by depositing an oxide material on the semiconductor material stack structures 11 using a conformal deposition process such as, for example, atomic layer deposition (ALD) or plasma-enhanced atomic layer deposition (PEALD). The oxide material used to from the gate dielectric 21 can include, but is not limited to, SiO2.

The dummy gate layer 23 is formed by depositing a dummy gate material on the semiconductor substrate 10, and covers the semiconductor material stack structures 11. The dummy gate layer 23 can be deposited using various deposition techniques including, for example, chemical vapor deposition (CVD), plasma enhanced chemical vapor deposition (PECVD), physical vapor deposition (PVD), sputtering, or ALD. According to a non-limiting embodiment, the dummy gate material is a silicon material such as, for example, polysilicon or amorphas silicon (a-Si).

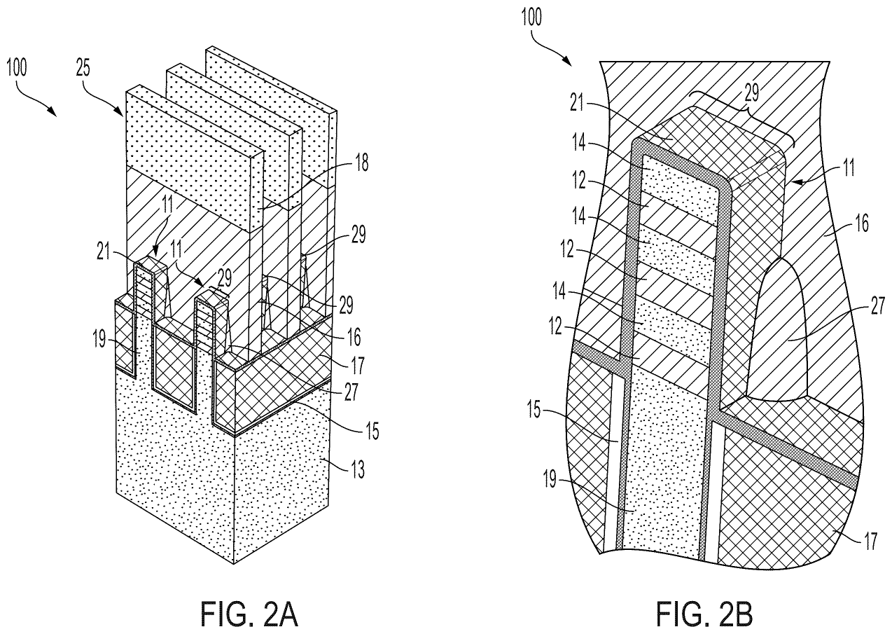

Turning now to FIGS. 2A and 2B, the semiconductor device 100 is illustrated after patterning the dummy gate layer 23 to form a sacrificial gate structure 25 on the semiconductor material stack structure 11. In the illustrated embodiment, the sacrificial gate structure 25 includes a sacrificial gate portion 16 and a sacrificial dielectric cap portion 18. Each sacrificial gate structure 25 is located on a first side and a second side of the semiconductor material stack structure 11 and spans across a topmost surface of a portion of the semiconductor material stack structure 11. The first side and second sides of the semiconductor material stack structure 11 located on opposing sides of each sacrificial gate structure 25 are designated as source/drain regions 29 (e.g., designated source/drain regions 29) at which source/drains (not shown) can be formed during a subsequent stage of the process flow. The gate dielectric 21 extends from beneath the sacrificial gate structure 25 and covers the source/drain regions 29.

According to a non-limiting embodiment, each sacrificial gate structure 25 includes a sacrificial gate portion 16 and a sacrificial dielectric cap portion 18. In some embodiments, the sacrificial dielectric cap portion 18 can be omitted. Although the sacrificial gate portion 16 is shown as including one layer, it should be appreciated that additional sacrificial layers may be utilized to form the sacrificial gate portion 16.

The sacrificial gate portion 16 can be formed by depositing a dielectric cap material on the upper surface of the dummy gate layer 23, performing a lithography and a first etching process that patterns the dielectric cap material to form the sacrificial dielectric cap portions 18, and performing a second etching process (e.g., a RIE) that transfers the pattern defined by the sacrificial dielectric cap portions 18 into the dummy gate layer 23. The sacrificial gate cap material may include a hard mask material such as, for example, silicon dioxide and/or silicon nitride. The sacrificial gate cap material of the sacrificial dielectric cap portion 18 can be formed by any suitable deposition process such as, for example, chemical vapor deposition (CVD) or plasma enhanced chemical vapor deposition (PECVD). The gate RIE used to form each sacrificial gate structure 25 results in the formation of a gate skirt 27, which is a residual amount of the dummy gate layer 23 located at an interface shared by the semiconductor material stack structure 11 and the sacrificial gate structure 25. For example, the gate skirt 27 may be formed such that it protrudes from a corner at which the semiconductor material stack structure 11 and the sacrificial gate structure 25 meet.

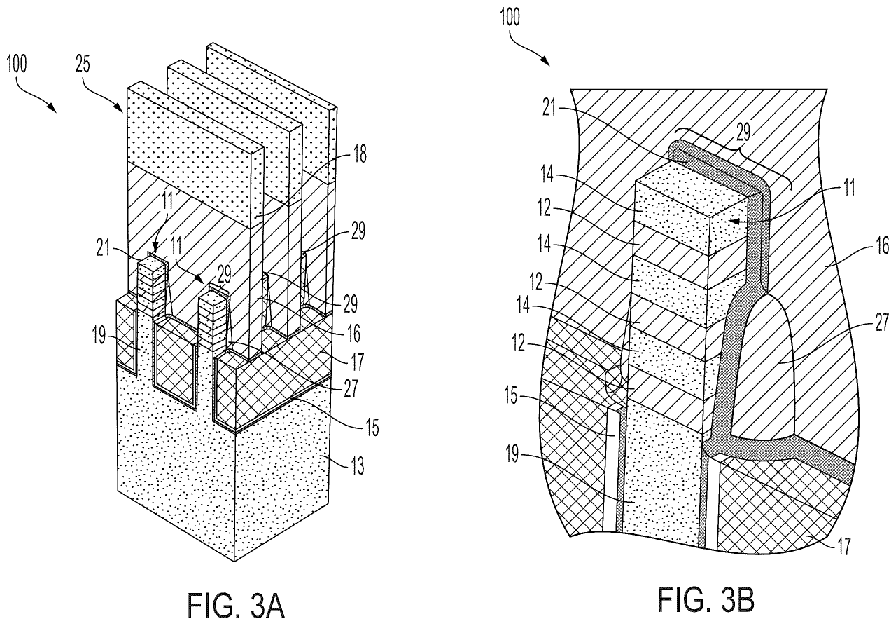

Turning to FIGS. 3A and 3B, the semiconductor device 100 is illustrated after performing an extended gate (EG) dielectric removal process to remove the gate dielectric 21 from the source/drain regions 29 of the semiconductor material stack structures 11. According to a non-limiting embodiment, a RIE can be performed to vertically etch the semiconductor material stack structure 11 and remove the gate dielectric 21 from the upper surface of the semiconductor material stack structures 11 while maintaining a portion of the gate dielectric 21 beneath the sacrificial gate structure 25.

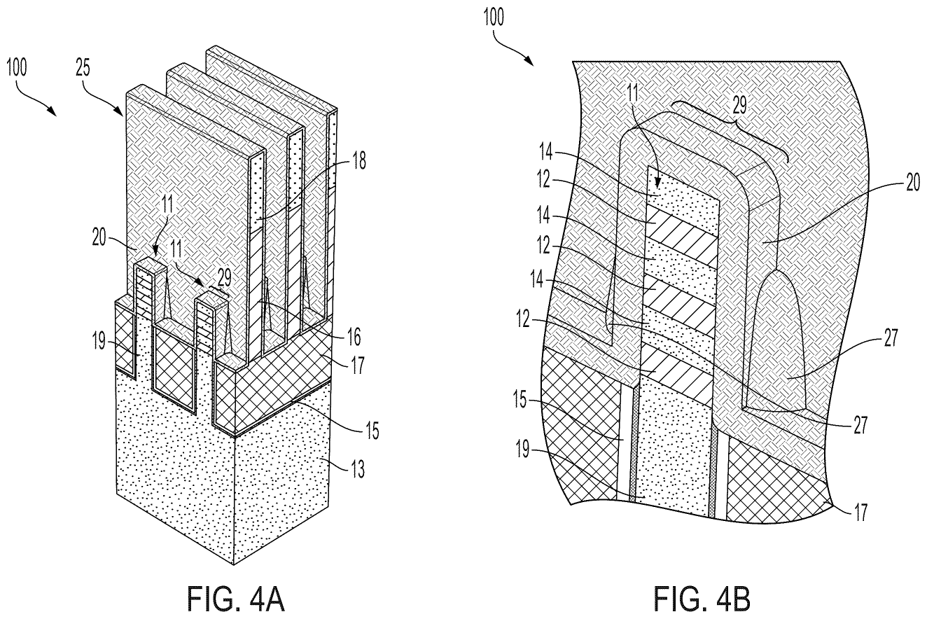

Referring now to FIGS. 4A and 4B, the semiconductor device 100 is shown after forming a gate spacer 20 on a sidewall of the sacrificial gate structure 25. In one or more non-limiting embodiments, the gate spacer 20 can also span across the semiconductor material stack structure 11 and completely covers the gate skirt 27. Examples of dielectric spacer materials that may be employed in the present application are silicon nitride (SiN), siliconboron carbonitride (SiBCN), or silicon oxycarbonitride (SiOCN). The dielectric spacer material used to form the gate spacer 20 can be deposited according to various deposition process including, for example, chemical vapor deposition (CVD), plasma enhanced chemical vapor deposition (PECVD), or physical vapor deposition (PVD).

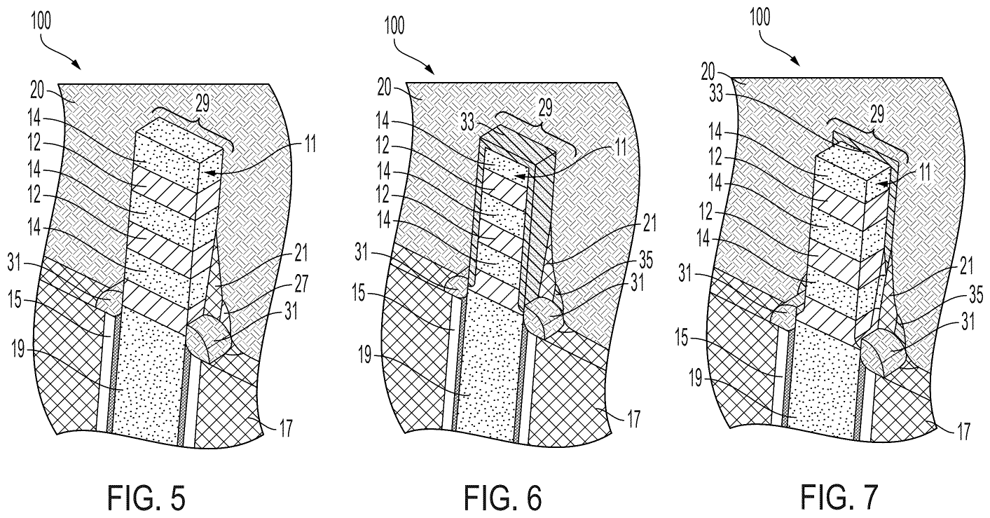

In FIG. 5, the semiconductor device 100 is shown after etching a portion of the gate spacer 20 from the upper surface and sidewalls of the semiconductor material stack structure 11. In one or more non-limiting embodiments, a portion of the gate spacer 20 is removed from an upper portion of the sacrificial gate structure 25 to expose the sacrificial dielectric cap portions 18 (see FIG. 4A).

The etch used to remove portions of the gate spacer 20 can include a dry etching process such as, for example, RIE. Removing portions of the gate spacer 20 exposes the semiconductor material stack structure 11 (e.g., the sacrificial semiconductor material 12 and the semiconductor channel material 14) located in the source/drain regions 29, a portion of the gate dielectric 21, and a portion of the gate skirt 27. A residual portion of the dielectric spacer material following the RIE defines gate spacer extensions 31, which are formed on the insulator layer 17 and against sidewalls of the semiconductor material stack structure 11. In an embodiment, the gate spacer extensions 31 are located at opposing ends of the source/drain region 29. Accordingly, the gate spacer extensions 31 can be used to control the width of the source/drain region 29 (e.g., the upper surface of the semiconductor fins 19) from extending significantly, thereby preventing contact with neighboring S/D regions to avoid shorting devices.

Referring now to FIG. 6, the semiconductor device 100 is shown after performing a nitridation process. The nitridation process converts exposed silicon material of the semiconductor material stack structure 11 (e.g., the sacrificial semiconductor material 12 and the semiconductor channel material 14) and the gate skirt 27 into silicon nitride (SiN). Accordingly, the nitridation process forms a nitride liner 33 that conforms to the upper surface and sidewalls of the semiconductor material stack structure 11, and converts any exposed portion of the gate skirt 27 into a dielectric plug 35 (e.g., a nitride plug) that plugs or fills the area previously occupied by the previously exposed portion of the gate skirt 27. According to an embodiment, the dielectric plug 35 is an integral portion of the gate spacer and is located between the source/drain region 29 and the gate spacer 20. As described herein, FIG. 6 is a three-dimensional cross sectional view of the semiconductor device 100, which may continuously extend to another semiconductor device (not shown). In such a non-limiting embodiment, the silicon material of the semiconductor material stack structure 11 (e.g., the sacrificial semiconductor material 12 and the semiconductor channel material 14) will be covered and will not be converted into a nitride material. In some non-limiting embodiments where the semiconductor device 100 is an edge device (not shown), the exposed portions of the silicon material of the semiconductor material stack structure 11 (e.g., the sacrificial semiconductor material 12 and the semiconductor channel material 14) will be converted into a nitride material.

Turning to FIG. 7, the semiconductor device 100 is shown after removing the nitride liner 33 from the semiconductor material stack structure 11. A RIE process can be performed to remove the nitride liner from the upper surface and sidewalls of semiconductor material stack structure 11, while maintaining the dielectric plug 35. According to a non-limiting embodiment, a portion of the nitride liner 33 can be at an interface shared between the semiconductor material stack structure 11 and the gate spacer 20.

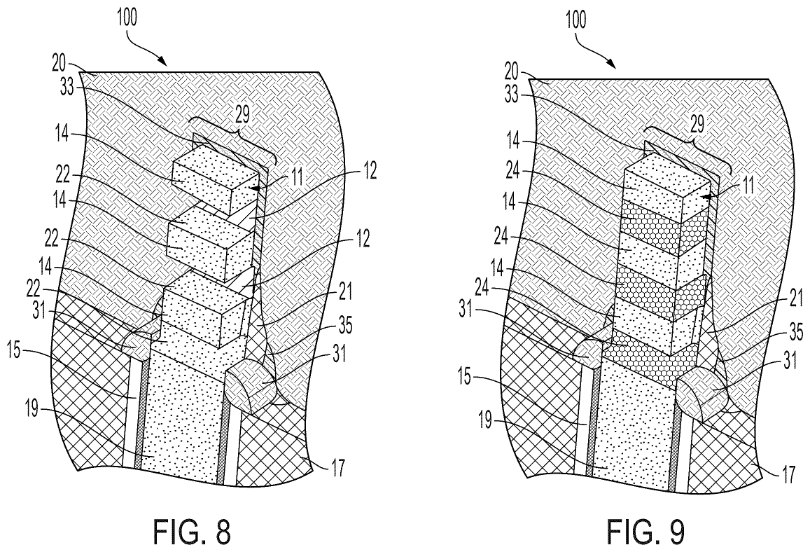

In FIG. 8, the semiconductor device 100 is shown after recessing each layer of the sacrificial semiconductor material 12. Each (recessed) layer of sacrificial semiconductor material 12 has a width (e.g., extending along the Y-axis) that is less than the original length of the sacrificial semiconductor material 12 and the semiconductor channel material 14. The recessing of the sacrificial semiconductor material 12 provides a gap 22 between each neighboring layer of semiconductor channel material 14 within a given semiconductor material stack structure 11. A gap 22 is also formed between the bottommost semiconductor channel material 14 (nanosheet) and the semiconductor substrate 10 (e.g., the semiconductor fins 19). The recessing of the sacrificial semiconductor material 12 can be performed using a lateral etching process that is selective in removing physically exposed end portions of the sacrificial semiconductor material 12 relative to the semiconductor channel material 14 and the SiN material of the dielectric plug 35. Accordingly, the dielectric plug 35 prevents the formation of a void that would have occurred had the gate skirt 27 been exposed when recessing the sacrificial semiconductor material 12.

Turning to FIG. 9, the semiconductor device 100 is illustrated after depositing a dielectric material on physically exposed surfaces of each recessed sacrificial semiconductor material 12 and within each gap 22 (shown in FIG. 8) to form inner dielectric spacers 24. The inner dielectric spacers are formed between each semiconductor channel material 14. According to a non-limiting embodiment, the inner dielectric spacers 24 are formed by depositing the dielectric material and then performing an etching process that etches the dielectric material to define the inner dielectric spacers 24. The dielectric material can be the same material as, or different from, the dielectric spacer material used to form the gate spacer 20. As is shown, the inner dielectric spacers 24 have an innermost sidewall that directly contacts a sidewall of one of the layers of (recessed) sacrificial semiconductor material 12, and an outermost sidewall that is vertically aligned with the sidewalls of each layer of semiconductor channel material 14. In a subsequent stage of the process flow (not shown), remaining portions of the layers of sacrificial semiconductor material 12 included in the semiconductor material stack structure 11 can be removed and replaced with one or more gate metals (not shown).

As described above, a process flow according to non-limiting embodiments illustrated in FIGS. 1A-9 implements a nitridation process prior to removing the sacrificial semiconductor material 12 from the semiconductor material stack structure 11. The nitridation process converts the any exposed portions of the gate skirt 27 into a nitride material that serves as dielectric plug 35. The sacrificial semiconductor material 12 can then be selectively recessed with respect to the semiconductor channel material 14 and the dielectric plug 35. Accordingly, the dielectric plug 35 prevents formation of a void that would have occurred had the gate skirt 27 been exposed when recessing the sacrificial semiconductor material 12.

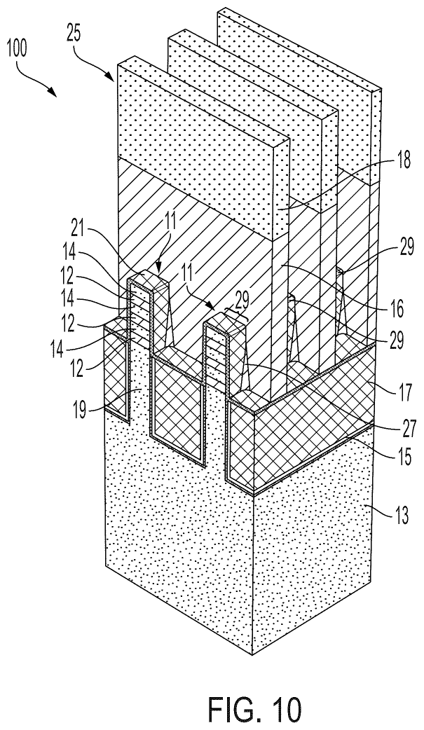

With reference now to FIGS. 10-16, a process flow and resulting structures that provide yield and variation improvement for a nanosheet semiconductor device are illustrated according to another non-limiting embodiment of the present disclosure. The process flow illustrated in FIGS. 10-16 may use one or more fabrications process utilized in the process flow described in FIGS. 1A-9. Therefore, likewise structures and fabrication processes may not be repeated for the sake of brevity.

FIG. 10 illustrates the semiconductor device 100 after patterning a dummy gate material to form a sacrificial gate structure 25 on each of the semiconductor material stack structures 11. As described herein, gate RIE used to form the sacrificial gate structures 25 results in the formation of a gate skirt 27, which is a residual amount of the dummy gate layer 23 that protrudes from a corner at which the semiconductor material stack structure 11 and sacrificial gate structure 25 meet.

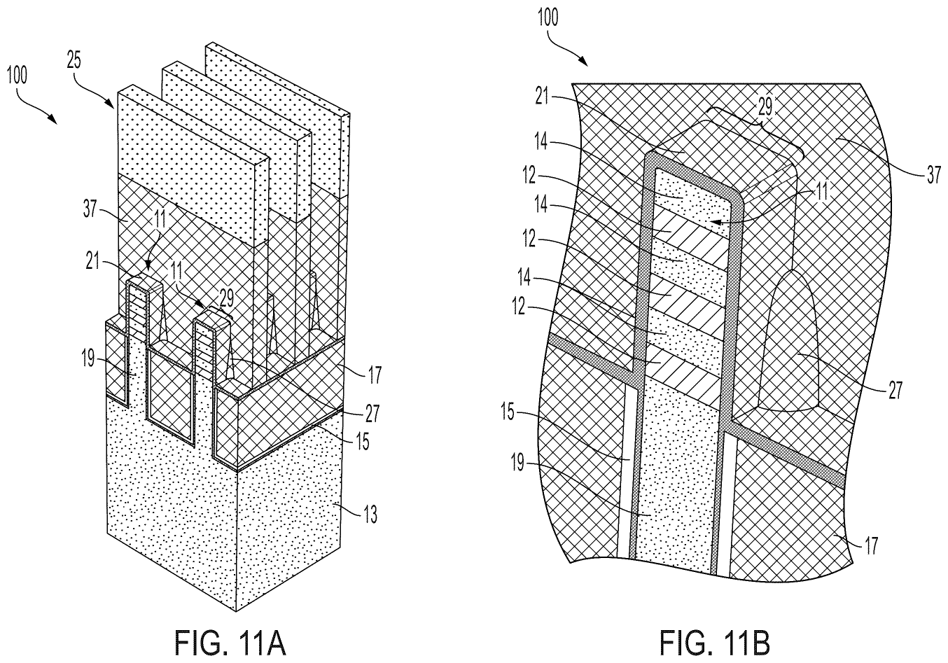

Turning to FIGS. 11A and 11B, the semiconductor device 100 is illustrated after performing a thermal oxidation process. The thermal oxidation process reacts with the material (e.g., polysilicon, or a-Si) of the sacrificial gate portion 16 and the (entire) gate skirt 27 to form an oxide film 37. The oxide film 37 is an SiO₂ material, for example, and completely covers the gate skirt 27. According to an embodiment, the oxidation process reduces the footprint of the gate skirt 27.

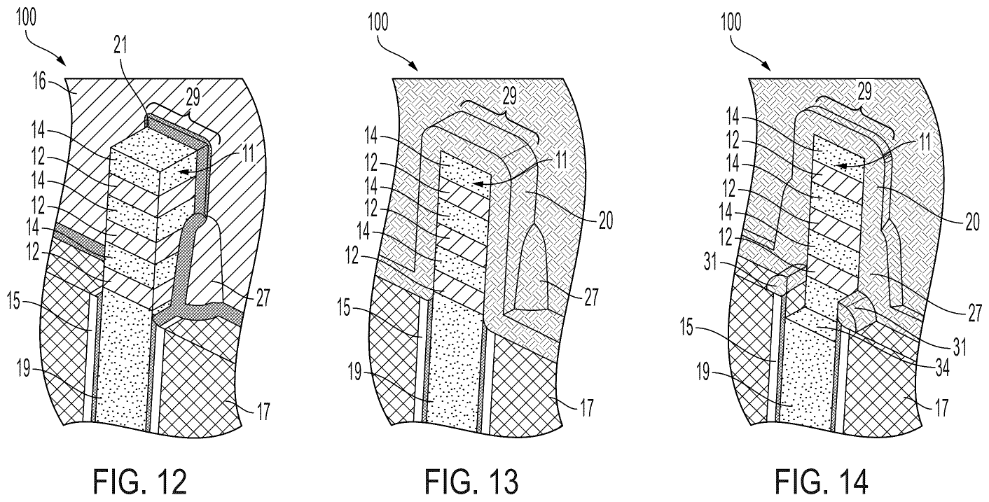

In FIG. 12, the semiconductor device 100 is illustrated after performing an extended gate (EG) dielectric removal process to remove the gate dielectric 21 from the source/drain regions 29 (e.g., the designated source/drain regions 29) of the semiconductor material stack structures 11. According to a non-limiting embodiment, a RIE can be performed to remove the gate dielectric 21 from the upper surface of the semiconductor material stack structures 11 and the while maintaining a portion of the gate dielectric 21 beneath the sacrificial gate structure 25. The EG dielectric process (e.g., the RIE) also removes the oxide film 37 from the sacrificial gate structures 25 and recesses the oxide film 37 from the gate skirt 27 to expose a portion of the gate skirt material (e.g., polysilicon or a-Si). In one or more non-limiting embodiments, the RIE may partially etch the gate skirt material thereby reducing the size of the gate skirt 27.

Turning to FIG. 13, the semiconductor device 100 is shown after forming a gate spacer 20 on a sidewall of the sacrificial gate structure 25. In one or more non-limiting embodiments, the gate spacer 20 can also span across the semiconductor material stack structure 11 and completely covers the gate skirt 27.

Referring now to FIG. 14, the semiconductor device 100 is shown after performing a stack recess operation that recesses the gate spacer 20 and a portion of the semiconductor material stack structure 11 located in the source/drain region 29. The stack recess operation forms a ledge 34 below the semiconductor material stack structure 11 and in the source/drain regions 29. The ledge 34 can be utilized to subsequently perform epitaxial growth of a source/drain (not shown). According to a non-limiting embodiment, a RIE can be used to recess the gate spacer 20 (e.g., vertically along the Z-axis) and the semiconductor material stack structure 11 located in the source/drain region 29. The RIE also reduces the width (e.g., along the Y-axis) of the gate skirts 27 covered by the gate spacer 20. As described above, the previous oxidation process can reduce the footprint of the gate skirt 27. Accordingly, the gate skirt 27 will not be exposed after recessing the gate spacer 20. Following the RIE process, a residual portion of the dielectric spacer material following the RIE defines gate spacer extensions 31, which are formed on the insulator layer 17 and adjacent sides of the semiconductor material stack structure 11. In a non-limiting embodiment, the gate spacer extensions 31 are located at opposing ends of the source/drain region 29. Accordingly, the gate spacer extensions 31 can be used to limit the width of the source/drain region 29 (e.g., the ledge 34) from extending significantly, thereby preventing contact with neighboring S/D regions to avoid shorting devices.

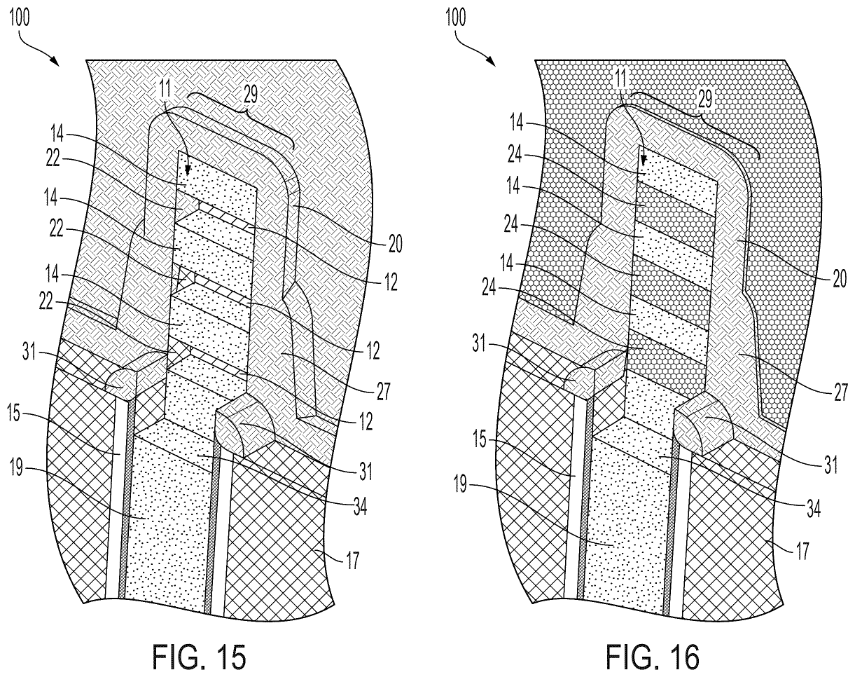

With reference to FIG. 15, the semiconductor device 100 is shown after recessing each layer of the sacrificial semiconductor material 12. Each recessed layer of sacrificial semiconductor material 12 has a width (e.g., extending along the Y-axis) that is less than the original length of the sacrificial semiconductor material 12 and the semiconductor channel material 14. The recessing of the sacrificial semiconductor material 12 provides a gap 22 between each neighboring layer of semiconductor channel material 14 within a given semiconductor material stack structure 11. The recessing of the sacrificial semiconductor material 12 can be performed using a lateral etching process that is selective in removing physically exposed end portions of the sacrificial semiconductor material 12 relative to the semiconductor channel material 14 and the nitride material (e.g., SiN) of the gate spacer 20. Accordingly, the nitride material covering the gate skirt 27 prevents the formation of a void that would have occurred had the gate skirt 27 been exposed when recessing the sacrificial semiconductor material 12.

Turning now to FIG. 16, the semiconductor device 100 is illustrated after forming a dielectric material 24 that define inner dielectric spacers on physically exposed surfaces of each (recessed) sacrificial semiconductor material 12 and within each gap 22 (shown in FIG. 15). The inner dielectric spacer 24 is formed by deposition of a dielectric spacer material and etching the deposited dielectric spacer material. The dielectric spacer material used to form the inner dielectric spacer 24 can be the same as, or different from, the dielectric spacer material used to form the gate spacer 20. For example, the inner dielectric spacer 24 can be formed from SiN or SiO2. In a subsequent stage of the process flow (not shown), remaining portions of the layers of sacrificial semiconductor material 12 included in the semiconductor material stack structure 11 can be removed and replaced with one or more gate metals (not shown).

As is shown, the inner dielectric spacer 24 has an innermost sidewall that directly contacts a sidewall of one of the layers of (recessed) sacrificial semiconductor material 12, and an outermost sidewall that is vertically aligned with the sidewalls of each layer of semiconductor channel material 14. In one or more embodiments of the invention, the deposition of a dielectric spacer material forms an additional dielectric layer on the exposed surfaces of the gate spacers 20. An etching process (e.g., a lateral planarization etch) can then be performed to planarize the gate spacers 20 and the semiconductor material stack structure 11 in a lateral direction (e.g., along the Y-axis). In this manner, the gate spacers 20 can be formed co-planar (e.g., “flush”) in relation to the semiconductor material stack structure 11.

As described above, a process flow according to non-limiting embodiments illustrated in FIGS. 10-16 implements a thermal oxidation process that forms an oxide film 37 that covers the gate skirt 27, and then etches the oxide film 37 where reduces the size of the gate skirt 27. The gate skirt 27 is completely covered with a nitride material following formation of the gate spacer 20. Accordingly, the sacrificial semiconductor material 12 can then be selectively recessed with respect to the semiconductor channel material 14 and the nitride material covering the gate skirt 27. In this manner, the void that would have occurred had the gate skirt 27 been exposed when recessing the sacrificial semiconductor material 12 can be avoided.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description, but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The present invention may be a system, a method, and/or a computer program product at any possible technical detail level of integration. The computer program product may include a computer readable storage medium (or media) having computer readable program instructions thereon for causing a processor to carry out aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of fabricating a semiconductor device comprising:
etching a dummy gate material to form a sacrificial gate structure and expose a semiconductor material stack structure, wherein a remaining amount of the dummy gate material defines a gate skirt located at an interface shared by the semiconductor material stack structure and the sacrificial gate structure;
forming gate spacers that cover the sacrificial gate structure, the semiconductor material stack structure, and the gate skirt;
etching a portion of the gate spacers to expose the semiconductor material stack structure and at least a portion of the gate skirt; and
performing a nitridation process that converts the portion of the gate skirt into a nitride plug.

2. The method of claim 1, wherein the gate skirt is formed from a silicon material and the nitride plug is formed from a nitride material.

3. The method of claim 1, wherein the silicon material is one of polysilicon or amorphous silicon, and the nitride material is silicon nitride.

4. The method of claim 1, wherein the semiconductor material stack structure includes alternating layers of a sacrificial semiconductor material and a semiconductor channel material.

5. The method of claim 4, further comprising:
performing a etching process that is selective to the sacrificial semiconductor material with respect the nitride plug to form gaps in the semiconductor material stack structure; and
filling the gaps with a dielectric material to form inner dielectric spacers in the semiconductor material stack structure.

6. The method of claim 5, wherein the sacrificial semiconductor material is a first type of semiconductor material and the semiconductor channel material is a second type of semiconductor material different from the first type of semiconductor material.

7. The method of claim 6, wherein the first type of semiconductor material is silicon germanium and the second type of semiconductor material is silicon.

8. A method of fabricating a semiconductor device comprising:
etching a dummy gate material to form a sacrificial gate structure and expose a semiconductor material stack structure wherein a remaining amount of the dummy gate material defines a gate skirt located at an interface shared by the semiconductor material stack structure and the sacrificial gate structure;
performing a thermal oxidation process to form an oxide film that covers the sacrificial gate structure and the gate skirt;
etching the oxide film;
forming gate spacers that cover the sacrificial gate structure and the semiconductor material stack structure; and
replacing layers of sacrificial semiconductor material included in the semiconductor material stack structure with inner dielectric spacers.

9. The method of claim 8, wherein the semiconductor material stack structure includes alternating layers of the sacrificial semiconductor material and a semiconductor channel material that are stacked in a vertical direction extending along a first axis.

10. The method of claim 9, wherein the gate spacers are formed from a nitride material.

11. The method of claim 10, wherein replacing the layers of sacrificial semiconductor material comprises:
performing a lateral etching process that is selective to the sacrificial semiconductor material with respect the nitride material of the gate spacers to form gaps in the semiconductor material stack structure; and
filling the gaps with a dielectric material to form the inner dielectric spacers.

12. The method of claim 11, wherein the inner dielectric spacers are formed from one of silicon dioxide or silicon nitride.

13. The method of claim 11, further comprising:
prior to replacing the layers of sacrificial semiconductor material, recessing the gate spacers and the semiconductor material stack structure in a lateral direction that extends along a second axis orthogonal to the first axis.

14. The method of claim 13, further comprising:
performing a lateral planarization etch such that the gate spacers 20 are co-planar in relation to the semiconductor material stack structure.

15. A semiconductor device comprising:
a semiconductor substrate including an insulator layer surrounding a semiconductor fin;
a semiconductor material stack structure on the semiconductor fin;
a sacrificial gate structure on the semiconductor material stack structure;
a gate spacer covering the sacrificial gate structure and the semiconductor material stack structure; and
gate spacer extensions on the insulator layer and against sidewalls of the semiconductor material stack structure.

16. The semiconductor device of claim 15, wherein the gate spacer extensions are located at opposing ends of a source/drain region of the semiconductor device.

17. The semiconductor device of claim 15, wherein the gate spacer extensions include a nitride material.

18. The semiconductor device of claim 16, further comprising a dielectric plug located between the source/drain region and the gate spacer.

19. The semiconductor device of claim 15, further comprising a ledge below the semiconductor material stack structure.

20. The semiconductor device of claim 15, wherein the semiconductor material stack structure includes alternating layers of a semiconductor channel material and dielectric material.
